(19) United States
(12) Patent Application Publication
(10) Pub. No.: US 2008/0203557 A1
(43) Pub. Date: Aug. 28, 2008

(54) SEMICONDUCTOR MODULE AND METHOD OF MANUFACTURING THE SAME

(75) Inventors: Tetsuya Yamamoto, Hashima-City (JP); Yoshio Okayama, Anpachi-gun (JP); Yasuyuki Yanase, Anpachi-gun (JP); Tetsuro Sawai, Hashima-city (JP)

Correspondence Address: FISH & RICHARDSON P.C., P.O. BOX 1022, MINNEAPOLIS, MN, 55440-1022, US

(73) Assignee: Sanyo Electric Co., Ltd., Osaka (JP)

(21) Appl. No.: 12/022,487

(22) Filed: Jan. 30, 2008

(30) Foreign Application Priority Data
Jan. 30, 2007 (JP) 2007-020136
Jan. 31, 2007 (JP) 2007-021882

(51) Int. Cl. H01L 23/12; H01L 21/44

(52) U.S. Cl. 257/700; 438/612; 257/E23.012

(57) ABSTRACT

Warp of a circuit device manufactured by the wafer level packaging technology is reduced. A semiconductor substrate used in a circuit device is provided with a circuit device and electrodes connected to the circuit device. A wiring layer having bumps connected to the electrodes is provided on a major surface of the semiconductor substrate. A metal layer is provided on a surface opposite to the major surface of the semiconductor substrate.

### CROSS-REFERENCE TO RELATED APPLICATIONS

This application is based upon and claims the benefit of priority from the prior Japanese Patent Applications No. 2007-020136, filed Jan. 30, 2007, and Japanese Patent Application No. 2007-021882, filed Jan. 31, 2007, the entire contents of which are incorporated herein by reference.

### BACKGROUND OF THE INVENTION

1. Field of the Invention

The present invention relates to semiconductor modules and methods of manufacturing the same.

2. Description of the Related Art

A package called chip size package (CSP) is known as a type of related-art semiconductor module. A semiconductor module of CSP type is formed by dicing a semiconductor wafer (semiconductor substrate) a major surface of which is provided with an LSI (semiconductor device) and an electrode (for external connection) connected to the LSI, so as to produce individual modules. Thus, a semiconductor module of CSP type can be bonded to a wiring board in a size substantially equal to a LSI chip, facilitating size reduction of a wiring b on which a semiconductor module is built.

Recently, with the trend toward miniaturization and high performance of electronic appliances, there is an increasing demand for reduction of the size of semiconductor modules used in electronic devices. In association with miniaturization of semiconductor modules, electrodes built on a wiring board should have narrow gaps. Flip-chip packaging is known as one method of building a package on the surface of a semiconductor module. In flip-chip packaging, a solder bump is formed on an electrode (for external connection) on a semiconductor module so that the solder bump and an electrode pad of the wiring board are soldered. In flip-chip packaging, efforts for narrowing the gap between electrodes have been successful only to a limited degree due to the constraints imposed by the size of solder bumps and solder bridges produced. Recently, there are attempts to relocate the electrodes by forming rewiring lines in a semiconductor module in an effort to overcome the limitation. For relocation, a metal plate may be half-etched so that a resultant bump (projection) is used as an electrode or a via, a semiconductor module is mounted on the metal plate via an insulating layer of, for example, epoxy resin, and the electrode for external connection of the semiconductor module is connected to the bump.

When a rewiring is formed by press work while a plurality of semiconductor devices are provided on a semiconductor substrate (i.e., while a wafer is not diced), the wafer may be warped in the cooling process following the press work due to a difference in coefficient of thermal expansion between the semiconductor substrate and the metal forming the rewiring (e.g. copper). When the wafer is warped, cracks may develop, or the wafer surface may lie outside the depth of focus in the subsequent lithographic steps, preventing exposure from being properly performed.

As the size of a semiconductor module is reduced, the density of heat is increased accordingly, so that there is an associated, dramatic increase in the temperature of a semiconductor module in operation. Therefore, it is essential to further improve the heat dissipation of a semiconductor module in order to operate the semiconductor module in a stable manner.

### SUMMARY OF THE INVENTION

In this background, a general purpose of the second embodiment to provide a technology capable of reducing warp in manufacturing a semiconductor module using the wafer level process technology. Another purpose of the present invention is to provide a technology capable of improving the heat dissipation of a semiconductor module provided with a rewiring pattern.

The semiconductor module comprises: a semiconductor substrate on which are formed a semiconductor device and an electrode electrically connected to the semiconductor device; a wiring layer having a bump electrically connected to the electrode on a major surface of the semiconductor substrate; an insulating layer provided between the semiconductor substrate and the wiring layer and adapted to undergo plastic flow when applied pressure; an electrode for external connection electrically connected to the wiring layer; a metal layer provided on a surface opposite to the major surface of the semiconductor substrate.

In this embodiment, the wiring layer may comprise rolled metal. Alternatively, a stress relaxation layer formed of an insulator may be provided between the metal layer and the semiconductor substrate.

Another aspect of the present invention relates to a method of manufacturing a semiconductor module. The method of manufacturing a semiconductor module comprises: forming a wiring layer provided with a bump by working a metal plate; pressure-bonding the wiring layer on a major surface of the semiconductor substrate via an insulating layer adapted to undergo plastic flow when applied pressure, a semiconductor device and an electrode electrically connected to the semiconductor device being formed on the semiconductor substrate; and forming a metal layer on a surface opposite to a major surface of the semiconductor substrate. The step of forming a metal layer and the step of pressure-bonding the wiring layer may be performed simultaneously.

The method may further comprise providing a stress relaxation layer formed of an insulator on a surface opposite to the major surface of the semiconductor substrate, before providing the metal layer, and the metal layer may be provided on a surface opposite to the major surface of the semiconductor substrate via the stress relaxation layer.

The method may further comprise forming a semiconductor device and an electrode in each of a plurality of areas in the semiconductor substrate, and then isolating, after providing the metal layer, the individual areas each including the semiconductor device and the electrode.

An embodiment of the present invention relates to a semiconductor module. The semiconductor module comprises: a semiconductor substrate on which are formed a semiconductor device and an electrode electrically connected to the semiconductor device; a wiring layer electrically connected to the electrode on a major surface of the semiconductor substrate; an insulating layer provided between the semiconductor substrate and the wiring layer; an electrode for external connection electrically connected to the wiring layer; a metal layer provided on a surface opposite to the major surface of the semiconductor substrate; and a high emissivity layer provided on the metal layer.

In this embodiment, the surface of an area in the metal layer characterized by relatively high temperature during operation may be flat. A trench may be formed on the surface thereof characterized by relatively low temperature during operation. In this case, an end of the trench may be connected to the flat part.

Another embodiment of the present invention relates to a method of manufacturing a semiconductor module. The method of manufacturing a semiconductor module comprises: forming, via an insulating layer, a wiring layer on a major surface of the semiconductor substrate on which are formed a semiconductor device and an electrode electrically connected to the semiconductor device; forming a metal layer on a surface opposite to the major surface of the semiconductor substrate; and forming a high emissivity layer on the metal layer. In this embodiment, the step of forming a metal layer and the step of pressure-bonding the wiring layer may be performed simultaneously. According to the embodiment, the steps in the method of manufacturing a semiconductor module are simplified and shortened in time, and the manufacturing cost is reduced. A high emissivity layer is defined as a layer with a emissivity of 0.8 or greater.

In this embodiment, the method may further comprise forming a trench in an area of the surface of metal layer characterized by relatively low temperature during operation, before forming the high emissivity layer. An end of the trench may be connected to an area of the surface of the metal layer characterized by relatively low temperature during operation.

It is to be noted that any arbitrary combination or rearrangement of the above-described structural components and so forth are all effective as and encompassed by the present embodiments.

Moreover, this summary of the invention does not necessarily describe all necessary features so that the invention may also be sub-combination of these described features.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a schematic sectional view of a semiconductor module according to a first embodiment.

FIGS. 2A-2E are sectional views showing the steps of manufacturing a copper plate used in the process of manufacturing the semiconductor module according to the first embodiment.

FIGS. 3A-3D are sectional views of the steps showing the process of manufacturing the semiconductor module according to the first embodiment.

FIG. 4 is a top view showing a semiconductor wafer with a matrix of semiconductor substrates defined by a plurality of scribe lines.

FIGS. 5A-5C are sectional views of the steps showing the process of manufacturing the semiconductor module according to the first embodiment.

FIGS. 6A-6B are sectional views of the steps showing the process of manufacturing the semiconductor module according to the first embodiment.

FIG. 7 shows warp of a semiconductor substrate.

FIG. 8 is a schematic sectional view of a semiconductor module according to a second embodiment.

FIG. 9A is a top view of a metal layer used in the semiconductor module according to the second embodiment.

FIGS. 9B and 9C are sectional views taking along the A-A line and the B-B line of FIG. 9A, respectively.

FIGS. 10A-10E are sectional views showing the steps of manufacturing a copper plate used in the process of manufacturing the semiconductor module according to the second embodiment.

FIGS. 11A-11D are sectional views of the steps showing the process of manufacturing the semiconductor module according to the second embodiment.

FIG. 12 is a top view showing a semiconductor wafer with a matrix of semiconductor substrates defined by a plurality of scribe lines.

FIGS. 13A-13C are sectional views of the steps showing the process of manufacturing the semiconductor module according to the second embodiment.

FIGS. 14A-14C are sectional views of the steps showing the process of manufacturing the semiconductor module according to the second embodiment.

### DETAILED DESCRIPTION OF THE INVENTION

The invention will now be described by reference to the preferred embodiments. This does not intend to limit the scope of the present invention, but to exemplify the invention.

A description will be given, with reference to the drawings, of the embodiments embodying the present invention.

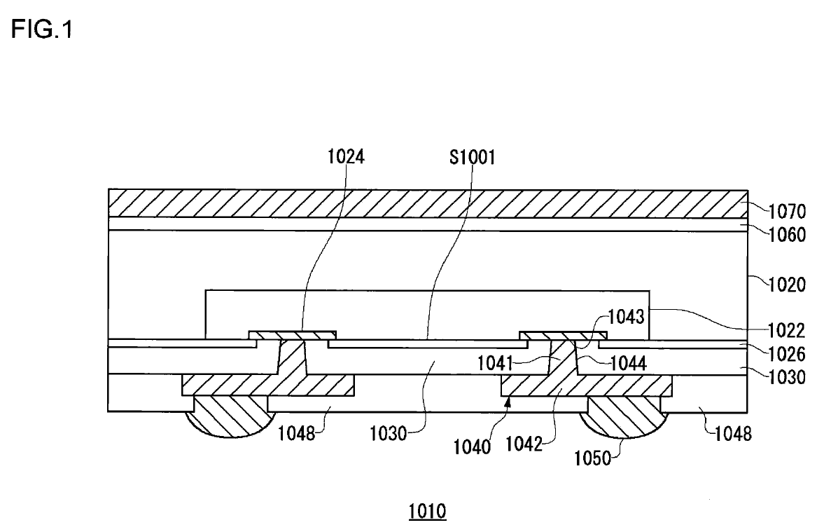

FIG. 1 is a schematic sectional view of a semiconductor module according to a first embodiment. A semiconductor module 1010 includes, as main features, a semiconductor substrate 1020, an insulating layer 1030, a wiring layer 1040, an electrode 1050 for external connection, a stress relaxation layer 1060, and a metal layer 1070. The semiconductor module 1010 according to this embodiment is manufactured by the wafer level packaging technology described later.

The semiconductor substrate 1020 is embodied by, for example, a p-type silicon substrate. A semiconductor device 1022 such as an LSI, and an electrode 1024 electrically connected to the semiconductor device 1022 are formed on a major surface S1 (toward the bottom in FIG. 1) of the semiconductor substrate 1020 by using a well-known technology. A protective film 1026 is formed on the major surface S1 (toward the bottom in FIG. 1) of the semiconductor substrate 1020 outside the electrode 1024. The protective film 1026 may be a silicon oxide (SiO₂) film or a silicon nitride (SiN) film.

Adjacent to the major surface S1 of the semiconductor substrate 1020, the insulating layer 1030 is formed on the electrode 1024 and the protective film 1026. The insulating layer 1030 is formed of a material that undergoes plastic flow when applied pressure. For example, the insulating layer 1030 may comprise an epoxy thermosetting resin. For example, epoxy thermosetting resin used for the insulating layer 1030 may be a material exhibiting the viscosity of 1 kpa*s at the temperature of 160° C. and the pressure of 8 MPa. If the material is pressured at 15 MPa under the temperature of 160° C., the viscosity of the resin will drop to ⅛ the level exhibited when the resin is not pressured. Below the glass-transition temperature Tg, epoxy resin in the B stage prior to thermosetting exhibits low viscosity of the level exhibited when the resin is not pressured, and does not exhibit viscosity even when pressured.

The wiring layer (rewiring pattern) 1040 is formed on the insulating layer 1030. More specifically, the wiring layer 1040 is provided at a location corresponding to the electrode 1024. The layer 1040 is provided with a bump (projecting conductor) 1041 penetrating the insulating layer 1030 and connected to the exposed surface of the electrode 1024, and a rewiring 1042 integral with the bump 1041. A rolled metal comprising rolled copper may be used to form the wiring layer 1040. As compared with a metal film comprising copper and formed by, for example, plating, a rolled metal comprising copper excels in mechanical strength and is suitable as a material for rewiring. The rewiring 1042 has a thickness of about 30 μm, and the height (thickness) of the bump 1041 is about 60 μm. The bump 1041 is formed to be round, and is provided with an end part 1043 representing a surface of contact with the electrode 1024 of the semiconductor substrate 1020, and with a side part 1044 formed to be progressively smaller in diameter toward the end part 1043. The diameter of the bump 1041 at the end part 1043 and the diameter at the connection with the rewiring are about 40 μmφ and about 60 μmφ, respectively.

An electrode 1050 such as a solder bump for external connection is provided on the bottom surface of the wiring layer 1040. The gap between the electrodes 1050 is wider than the gap between the electrodes 1024. A photo solder resist layer 1048 is provided between the electrodes 1050. The photo solder resist layer 1048 reduces thermal damage applied when the electrode 1050 is soldered.

The stress relaxation layer 1060 is provided on a surface opposite to the major surface S1 of the semiconductor substrate 1020. The stress relaxation layer 1060 is formed by an insulator such as epoxy thermosetting resin. For example, the thickness of the stress relaxation layer 1060 is 30 μm. The stress relaxation layer 1060 buffers the stress developed in the semiconductor module 1010 and reduces the warp of the semiconductor module 1010.

The metal layer 1070 is provided on the stress relaxation layer 1060. The metal used to form the metal layer 1070 is the same as that of the wiring layer 1040 with the result that the metal layer 1070 and the wiring layer 1040 have the same coefficient of thermal expansion. The shape and thickness of the metal layer 1070 are defined according to the wiring pattern of wiring layer 1040. For example, the stress developed in the semiconductor substrate 1020 due to a difference in coefficient of thermal expansion between the wiring layer 1040 and the semiconductor substrate 1020 when the wiring layer 1040 is formed at 200° C. is canceled by the stress developed in the semiconductor substrate 1020 due to a difference in coefficient of thermal expansion between the metal layer 1070 and the semiconductor substrate 1020.

(Manufacturing Method)

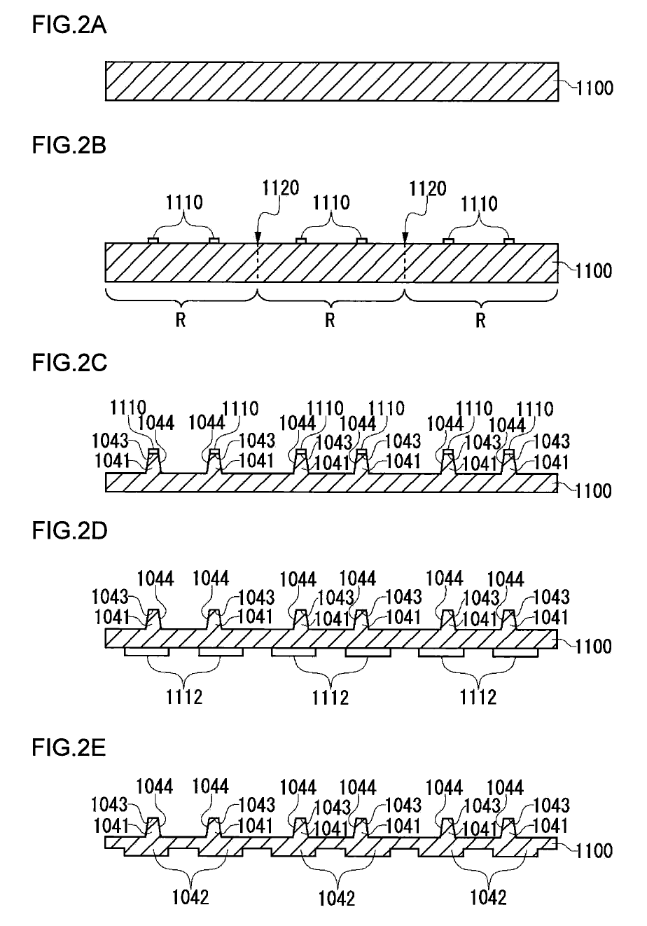

Firstly, as shown in FIG. 2A, a copper plate 1100 thicker than a sum of the height of the bump 1041 and the thickness of the rewiring layer 1042 as shown in FIG. 1 is prepared. It will be assumed here that the thickness of the copper plate 1100 is about 300 μm. A rolled metal comprising rolled copper may be used to form the copper plate 1100.

Then, as shown in FIG. 2B, well-known lithographic steps are used to form a resist mask 1110 in an area for bumps within each of areas R, defined by scribe lines 1120, where semiconductor modules are formed. The areas for bumps are arranged in association with the position of the electrodes in the semiconductor module area R.

Then, as shown in FIG. 2C, etching is performed by using the resist mask 1110 as a mask, so as to form the bump 1041 having a predetermined pattern on the copper plate 1100. By adjusting the etching conditions, the bump 1041 having the side part 1044 formed to be progressively smaller in diameter toward the end part 1043 is formed. It is assumed that the height of the bump 1041 is about 60 μm, and that the diameter of the bump 1041 at the end part 1043 and the diameter at the connection with the rewiring are about 40 μmφ and about 60 μmφ, respectively. A metal mask such as a silver (Ag) mask may be used in place of the resist mask 1110. With this, satisfactory etching selectivity ratio between the mask and the copper plate 1100 is ensured so that the bumps 1041 can be even finely patterned.

As shown in FIG. 2D, after removing the resist mask 1110, well-known lithographic steps are used to form a resist mask 1112 in a rewiring pattern in each area R, opposite to a surface provided with the bump 1041.

Then, as shown in FIG. 2E, by performing half-etching by using the resist mask 1112 as a mask, the copper plate 1100, outside the rewiring pattern area, is selectively removed, and then the resist mask 1112 shown in FIG. 2D is removed. With this, the copper plate 1100 is obtained, on one surface of which is formed the bump 1041 and on the other surface of which is formed the rewiring 1042, which corresponds to the bump 1041.

The copper plate 1100 thus manufactured is used in the process described below of manufacturing the semiconductor module according to the first embodiment.

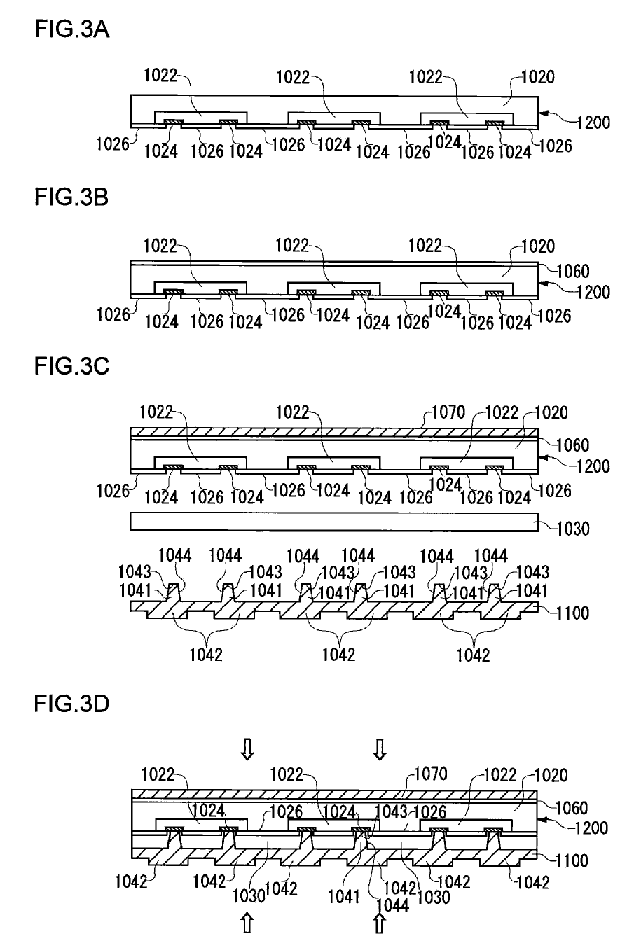

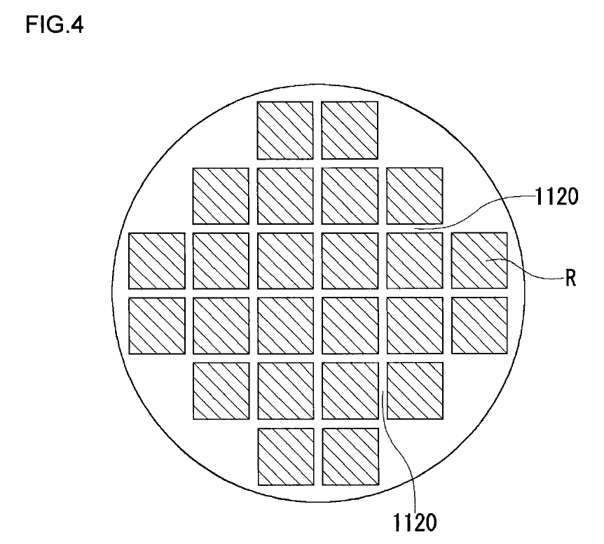

Firstly, as shown in FIG. 3A, a semiconductor wafer 1200 is prepared on one surface of which is formed a matrix of semiconductor substrates 1020 provided with the semiconductor device 1022, the electrode 1024, and the protective film 1026. As shown in FIG. 4, the semiconductor wafer 1200 is partitioned into a plurality of semiconductor module areas R by the plurality of scribe lines 1120. A semiconductor module is formed in each of the semiconductor module areas R.

More specifically, as shown in FIG. 3A, a well-known technology is used to form the semiconductor device 1022, such as an LSI, and the electrode connected to the semiconductor device 1022, on one surface (bottom surface) of each semiconductor substrate 1020 in a semiconductor wafer embodied by, for example, a p-type silicon substrate. A metal such as aluminum may be used to form the electrode 1024. The insulating protective film 1026 is formed in an area of the surface of the semiconductor substrate 1020 outside the electrode 1024. The protective film 1026 protects the semiconductor substrate 1020. The protective film 1026 may be a silicon oxide (SiO₂) film or a silicon nitride (SiN) film.

Then, as shown in FIG. 3B, the stress relaxation layer 1060 is formed on the upper surface of the semiconductor substrate 1020 by using a laminating device. The stress relaxation layer 1060 is formed by an insulator such as epoxy thermosetting resin. For example, the thickness of the stress relaxation layer 1060 is 30 μm.

Then, as shown in FIG. 3C, the metal layer 1070 is built on the stress relaxation layer 1060. The stress relaxation layer 1060 also functions as an adhesive layer for adhesively attaching the metal layer 1070. Like the wiring layer 1040 shown in FIG. 1, the metal layer 1070 is formed of copper. The metal layer 1070 and the wiring layer 1040 have the same coefficient of thermal expansion. The shape and thickness of the metal layer 1070 are defined according to the wiring pattern of wiring layer 1040. The insulating layer 1030 is sandwiched between the bottom surface of the semiconductor substrate 1020 and the copper plate 1100. The thickness of the insulating layer 1030 is about 60 μm, which is substantially equal to the height of the bump 1041.

Then, as shown in FIG. 3D, the semiconductor substrate 1020, the metal layer 1070, the insulating layer 1030, and the copper plate 1100 are integrated by pressure molding the assembly using a press machine. The pressure and the temperature of the press work are about 5 MPa and 200° C., respectively. The press work lowers the viscosity of the insulating layer 1030 so that the insulating layer 1030 undergoes plastic flow. This allows the bump 1041 to penetrate the insulating layer 1030 so that the bump 1041 and the electrode 1024 of the semiconductor substrate 1020 are electrically connected. Since the side part 1044 of the bump 1041 is formed to be progressively smaller in diameter toward the end part 1043, the bump 1041 penetrates the insulating layer 1030 smoothly in this process.

Since the metal layer 1070 is provided on a surface of the semiconductor substrate 1020 opposite to the wiring layer 1040, the stress developed in the semiconductor substrate 1020 due to a difference in coefficient of thermal expansion between the semiconductor substrate 1020 and the wiring layer 1040 balances the stress developed in the semiconductor substrate 1020 due to a difference in coefficient of thermal expansion between the semiconductor substrate 1020 and the metal layer 1070, in the cooling process. This reduces the warp of the semiconductor substrate 1020 so that the flatness of the semiconductor substrate 1020 is improved.

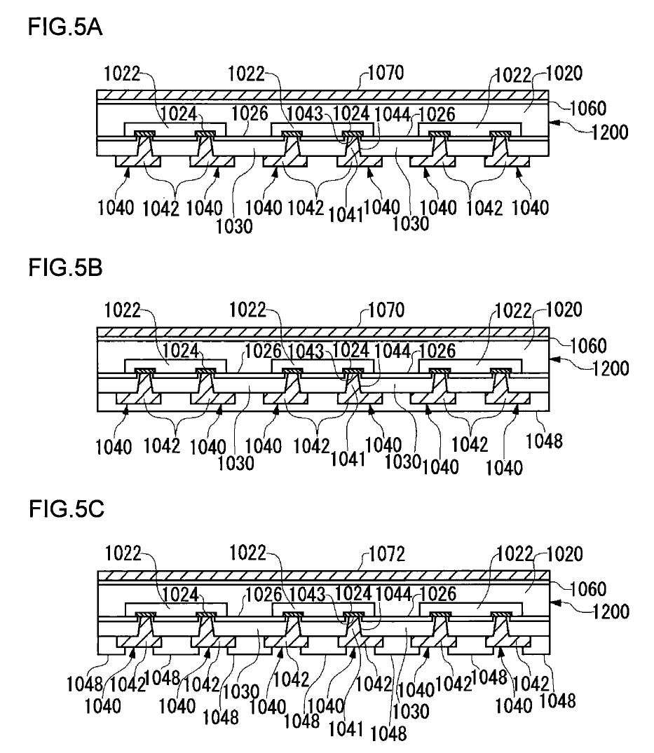

Then, as shown in FIG. 5A, by etching the entirety of the bottom surface of the copper plate 1100, parts unnecessary for rewiring are removed and the thickness of the wiring layer 1040 is adjusted. The thickness of the rewiring 1042 according to the example is about 30 μm.

Then, as shown in FIG. 5B, a surface roughener or the like is used to roughen the surface of the wiring layer 1040. Subsequently, the photo solder resist layer 1048 is built on the wiring layer 1040 and the insulating layer 1030 by using a laminating device.

Then, as shown in FIG. 5C, the photo solder resist layer 1048 outside the area for the electrode for external connection is selectively hardened by an exposure apparatus, followed by development for removal of the electrode area. Subsequently, the photo solder resist layer 1048 is further hardened by UV irradiation.

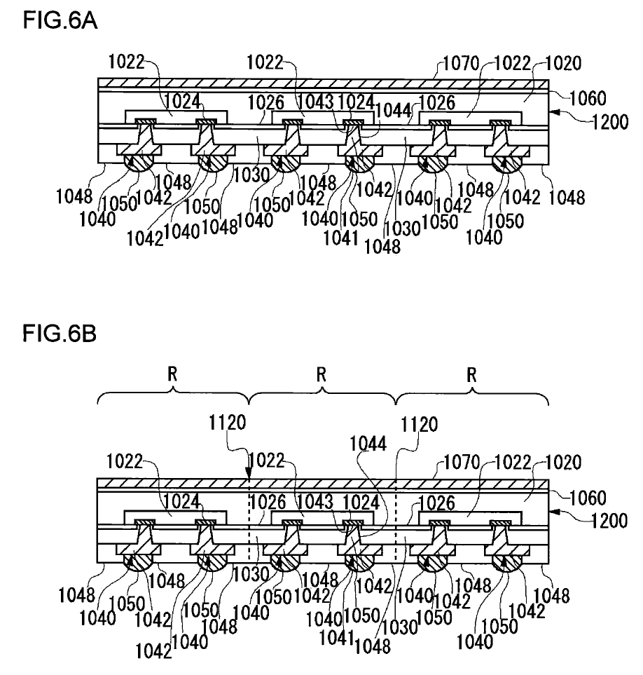

Then, as shown in FIG. 6A, solder printing is used to form the electrode (solder ball) 1050 which functions as a terminal for external connection in the wiring layer 1040. More specifically, the electrode 1050 is formed by printing solder paste (paste mixture of resin and solder) onto a desired location using a screen mask and heating the paste to a solder melting temperature. Alternatively, the wiring layer 1040 may be coated with flux before mounting the solder ball on the wiring layer 1040.

Then, as shown in FIG. 6B, individual semiconductor modules having the same outer dimension as the semiconductor substrate 1020 are produced by dicing the semiconductor wafer from beneath (underside) the wafer along the scribe lines 1120 which define the plurality of semiconductor module areas R. Residue created in the process of dicing is removed by cleaning using a chemical solution.

Through these steps, the semiconductor module according to the example shown in FIG. 1 is produced.

(Permitted Amount of Warp of a Semiconductor Module)

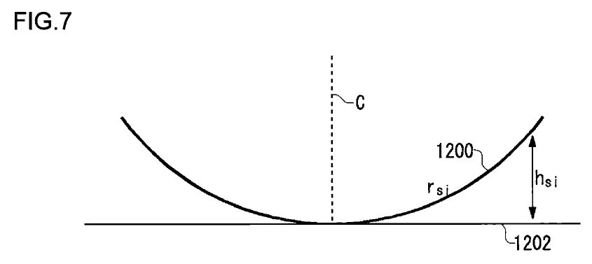

The depth of focus of an exposure apparatus is denoted by h, the radius of the semiconductor wafer rₛᵢ, and the warp of the semiconductor wafer 1200 hₛᵢ (see FIG. 7). The length of one side of the semiconductor module will be denoted by L. The warp hₛᵢ represents the distance between a plane 1202 contacted by the center C of the semiconductor wafer 1200 and the end of the semiconductor wafer 1200. In this case, the amount of warp h_{chip} permitted in a single semiconductor module will be given by the following expression. For example, given that hₛᵢ=100 μm, rₛᵢ=75 mm, and L=10 mm, it will be known that r_{chip}=1.8 μm from the following expression. According to the method of manufacturing semiconductor modules described above, the amount of warp in a 10 mm×10 mm semiconductor module can be controlled to 1.8 μm or smaller.

$${h}_{chip} = \frac{{r}_{si}^{2}}{2 {h}_{si}} ( 1 - cos ( \frac{2 {h}_{si} L}{{r}_{si}^{2}} ) )$$

### SECOND EMBODIMENT

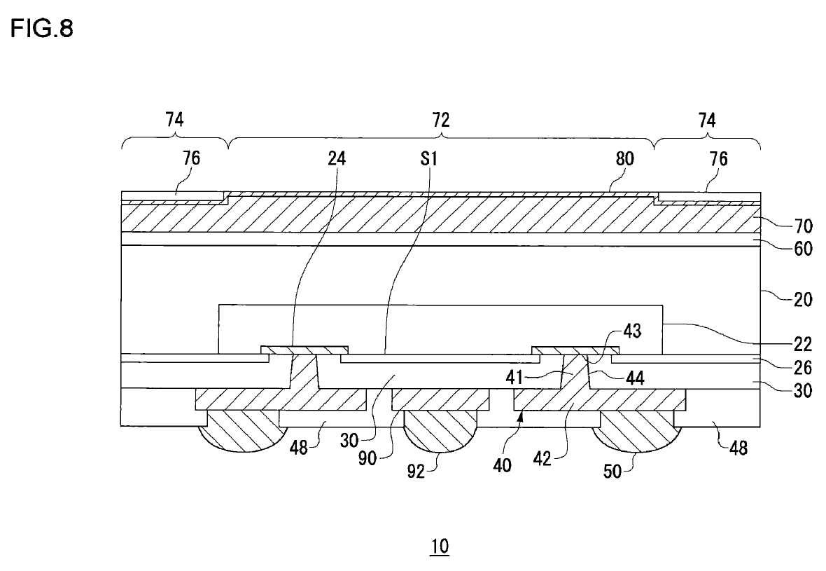

FIG. 8 is a schematic sectional view of a semiconductor module according to a second embodiment. A semiconductor module 10 includes, as main features, a semiconductor substrate 20, an insulating layer 30, a wiring layer 40, an electrode 50 for external connection, a stress relaxation layer 60, a metal layer 70, and a high emissivity layer 80. The semiconductor module 10 according to the first embodiment is manufactured by the wafer level packaging technology described later.

The semiconductor substrate 20 is embodied by, for example, a p-type silicon substrate. A semiconductor device 22 such as an LSI, and an electrode 24 electrically connected to the semiconductor device 22 are formed on a major surface S1 (toward the bottom in FIG. 8) of the semiconductor substrate 20 by using a well-known technology. A protective film 26 is formed on the major surface S1 (toward the bottom in FIG. 8) of the semiconductor substrate 20 outside the electrode 24. The protective film 26 may be a silicon oxide (SiO₂) film or a silicon nitride (SiN) film.

Adjacent to the major surface S1 of the semiconductor substrate 20, the insulating layer 30 is formed on the electrode 24 and the protective film 26. The insulating layer 30 is formed of a material that undergoes plastic flow when applied pressure. For example, the insulating layer 30 may comprise an epoxy thermosetting resin. For example, epoxy thermosetting resin used for the insulating layer 30 may be a material exhibiting the viscosity of 1 kpa*s at the temperature of 160° C. and the pressure of 8 MPa. If the material is pressured at 15 MPa under the temperature of 160° C., the viscosity of the resin will drop to ⅛ the level exhibited when the resin is not pressured. Below the glass-transition temperature Tg, epoxy resin in the B stage prior to thermosetting exhibits low viscosity of the level exhibited when the resin is not pressured, and does not exhibit viscosity even when pressured.

The wiring layer (rewiring pattern) 40 is formed on the insulating layer 30. More specifically, the wiring layer 40 is provided at a location corresponding to the electrode 24. The layer 40 is provided with a bump (projecting conductor) 41 penetrating the insulating layer 30 and connected to the exposed surface of the electrode 24, and a rewiring 42 integral with the bump 41. A rolled metal comprising rolled copper may be used to form the wiring layer 40. As compared with a metal film comprising copper and formed by, for example, plating, a rolled metal comprising copper excels in mechanical strength and is suitable as a material for rewiring. The rewiring 42 has a thickness of about 30 μm, and the height (thickness) of the bump 41 is about 60 μm. The bump 41 is formed to be round, and is provided with an end part 43 representing a surface of contact with the electrode 24 of the semiconductor substrate 20, and with a side part 44 formed to be progressively smaller in diameter toward the end part 43. The diameter of the bump 41 at the end part 43 and the diameter at the connection with the rewiring are about 40 μmφ and about 60 μmφ, respectively.

In this embodiment, a heat dissipating plate 90 not connected with the electrode 24 and having nothing to with the rewiring pattern is provided on the insulating layer 30. The heat dissipating plate 90 is formed of a metal of high heat conduction. Like the wiring layer 40, a rolled metal comprising rolled copper may be used to form the plate 90. Preferably, the heat dissipating plate 90 is provided at a location in which the temperature will be relatively high during operation. For example, the plate 90 may be provided below the semiconductor device 22.

An electrode 50 such as a solder bump for external connection is provided on the bottom surface of the wiring layer 40. The gap between the electrodes 50 is wider than the gap between the electrodes 24. A solder ball 92 for heat dissipation is provided on the bottom surface of the heat dissipation plate 90. The heat dissipation plate 90 and the solder ball 92 provide a channel for heat conduction so that the heat dissipation of the semiconductor module 10 is improved.

A photo solder resist layer 48 is provided between the electrode 50 and the solder ball 92. The photo solder resist layer 48 reduces thermal damage applied when the electrode 50 and the solder ball 92 are soldered.

The stress relaxation layer 60 is provided on a surface opposite to the major surface S1 of the semiconductor substrate 20. The stress relaxation layer 60 is formed of an insulator of high heat conduction such as epoxy thermosetting resin. For example, the thickness of the stress relaxation layer 60 is 30 μm. The stress relaxation layer 60 buffers the stress developed in the semiconductor module 10 and reduces the warp of the semiconductor module 10.

The metal layer 70 is provided on the stress relaxation layer 60. The metal used to form the metal layer 70 is the same as that of the wiring layer 40 with the result that the metal layer 70 and the wiring layer 40 have the same coefficient of thermal expansion. The shape and thickness of the metal layer 70 are defined according to the wiring pattern of wiring layer 40. For example, the stress developed in the semiconductor substrate 20 due to a difference in coefficient of thermal expansion between the wiring layer 40 and the semiconductor substrate 20 when the wiring layer 40 is formed at 200° C. is canceled by the stress developed in the semiconductor substrate 20 due to a difference in coefficient of thermal expansion between the metal layer 70 and the semiconductor substrate 20.

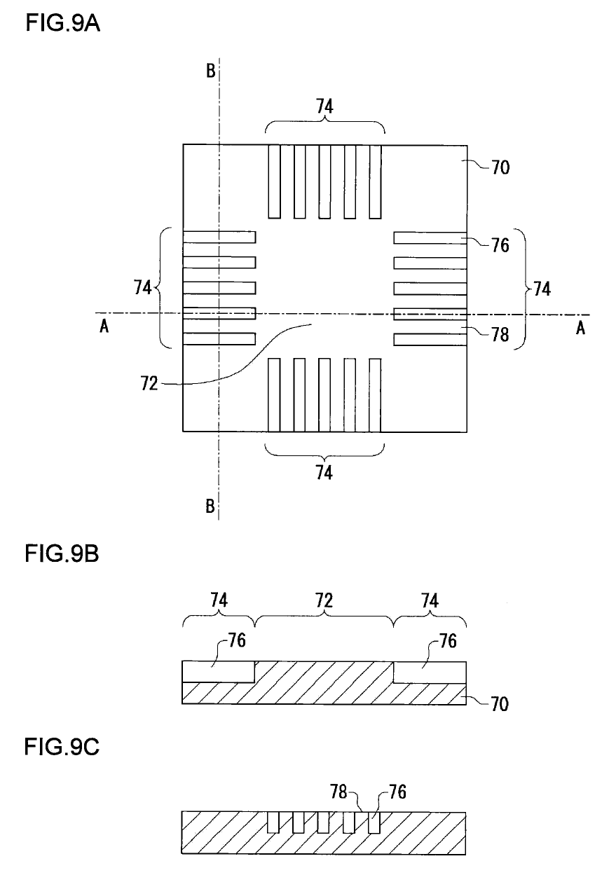

The metal layer 70 includes a flat part 72 with a flat surface and an unlevel part 74 in which a trench 74 is formed (see FIG. 9). The flat part 72 is provided in an area (hot spot) in which the temperature will be relatively high during operation. For example, the area in which the temperature is relatively high during operation is above the semiconductor device 22, which releases a large amount of heat.

The trench 76 provided in the unlevel part 74 is oriented so as to connect the periphery of the semiconductor module 10 and the flat part 72. One end of the trench 76 is connected to the flat part 72. Heat released as a result of the operation of the semiconductor module 10 induces air convection so that the air around the semiconductor module 10 flows to the flat part 72 via the trench 76. In this process, the air flows through the trench 76 so that the area of heat dissipation is increased. The flat part 72 dissipates heat by emission so that the upward flow of air is formed. In this way, the semiconductor module 10 can be efficiently cooled by naturally-occurring air convection and without providing complex structures of members.

The trench 76 provided in the unlevel part 74 may penetrate the stress relaxation layer 60 and reach the semiconductor substrate 20. With this, the heat dissipation of the semiconductor substrate 20 is further improved since the air is directly in contact with the semiconductor substrate 20.

The optimal values for the width of the trench 76 (interval between fins 78 between the adjacent trenches 76) and the number of fins 78 are given by expressions (1) and (2) below (see “Thermal calculation for resolving the heat dissipation issue of electronic devices and simulation technology”, Naoki Kunimine, Technical Information Institute Co., Ltd., 1351, p. 134).

$$\begin{matrix}{S}_{opt} [ mm ] = 5 \times {( Fin height a [ mm ] / Temperature increase of fin surface [ ° C . ] )}^{0.25} & ( 1 ) \\ Optimal No . of fins {N}_{opt} = \frac{( Fin width - Fin thickness )}{( Fin thickness + Optimal fin interval )} + 1 & ( 2 )\end{matrix}$$

Given that the height of the fin is 30 μm, the temperature increase on the fin surface is 50° C., the width of the fin is 10 mm, and the thickness of the fin is 1 mm, the optimal values for the width of the trench 76 and the number of fins 78 are 0.8 mm and 6.

The outermost surface of the metal layer 70 is covered by the high emissivity layer 80. Preferably, the high emissivity layer 80 is formed of a material having en emissivity of 0.8 or greater, or more preferably, 0.9 or greater. The high emissivity layer 80 may be formed by black paint like Aeroglaze (black Z306, Lord Chemical) or Nippe Nova 500 Astroblack (Astroblack, Nissan Paint), a metal oxide like copper oxide (emissivity of 0.8) or iron oxide (emissivity of 0.9), or a metal like molybdenum (emissivity of 0.9), titanium (emissivity of 0.8), black copper or dark brown copper, by way of examples.

By covering the outermost surface of the metal layer 70 with the high emissivity layer 80, heat stored in the semiconductor module 10 is easily dissipated by radiant heat transfer so that the heat dissipation of the semiconductor module 10 is improved. By ensuring that the surface of the metal layer 70 where the temperature will be relatively high during operation is flat, heat is efficiently dissipated by radiation in a high-temperature area.

(Manufacturing Method)

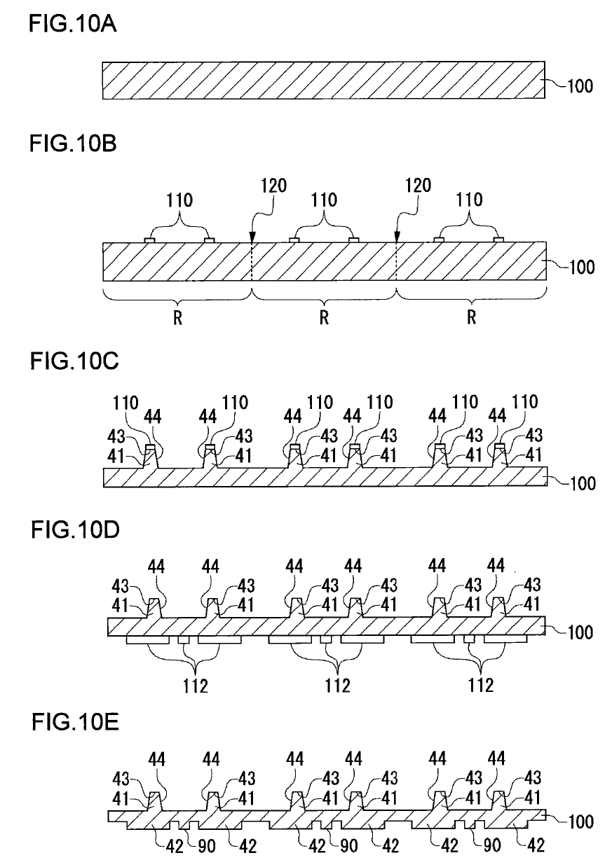

Firstly, as shown in FIG. 10A, a copper plate 100 thicker than a sum of the height of the bump 41 and the thickness of the rewiring layer 42 as shown in FIG. 8 is prepared. It will be assumed here that the thickness of the copper plate 100 is about 300 μm. A rolled metal comprising rolled copper may be used to form the copper plate 100.

Then, as shown in FIG. 10B, well-known lithographic steps are used to form a resist mask 110 in an area for bumps within each of areas R, defined by scribe lines 120, where semiconductor modules are formed. The areas for bumps are arranged in association with the position of the electrodes in the semiconductor module area R.

Then, as shown in FIG. 10C, etching is performed by using the resist mask 110 as a mask, so as to form the bump 41 having a predetermined pattern on the copper plate 100. By adjusting the etching conditions, the bump 41 having the side part 44 formed to be progressively smaller in diameter toward the end part 43 is formed. It is assumed that the height of the bump 41 is about 60 μm, and that the diameter of the bump 41 at the end part 43 and the diameter at the connection with the rewiring are about 40 μmφ and about 60 μmφ, respectively. A metal mask such as a silver (Ag) mask may be used in place of the resist mask 110. With this, satisfactory etching selectivity ratio between the mask and the copper plate 100 is ensured so that the bumps 41 can be even finely patterned.

As shown in FIG. 10D, after removing the resist mask 110, well-known lithographic steps are used to form a resist mask 112 in a rewiring pattern area and a heat dissipation plate area in each area R, opposite to a surface provided with the bump 41.

Then, as shown in FIG. 10E, by performing half-etching by using the resist mask 112 as a mask, the copper plate 100, outside the rewiring pattern area and the heat dissipation plate area, is selectively removed, and then the resist mask 112 shown in FIG. 10D is removed. With this, the copper plate 100 is obtained, on one surface of which is formed the bump 41 and on the other surface of which is formed the rewiring 42, which corresponds to the bump 41, and the heat dissipation plate 90.

The copper plate 100 thus manufactured is used in the process described below of manufacturing the semiconductor module according to the second embodiment.

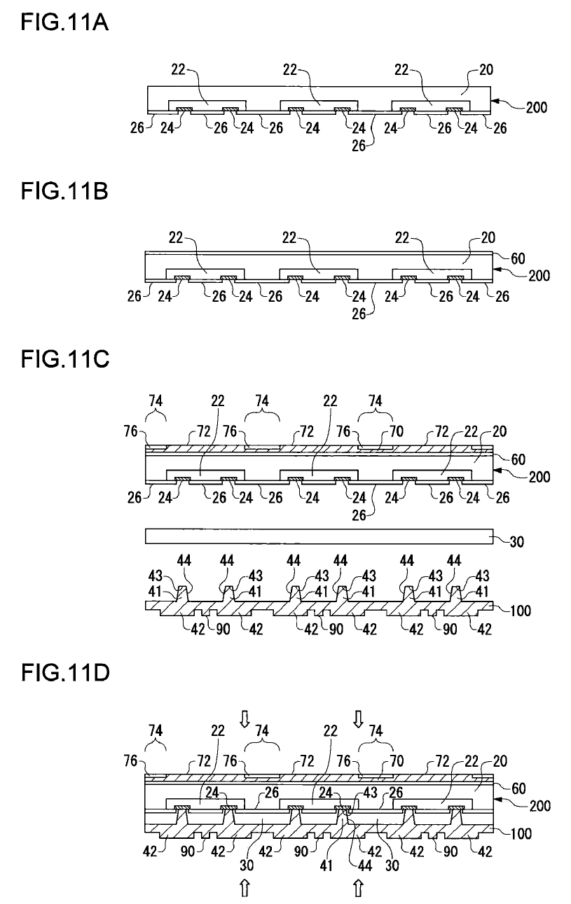

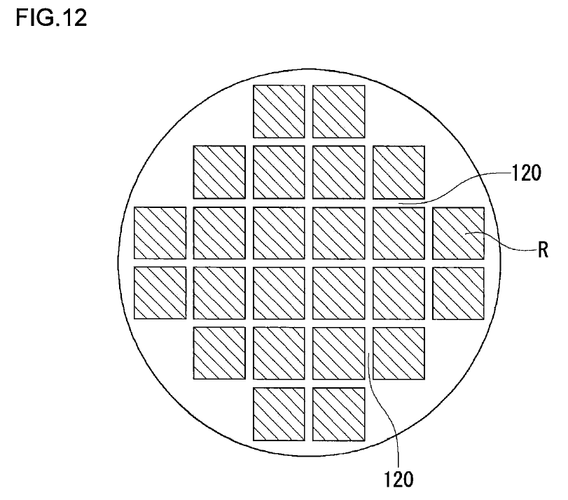

Firstly, as shown in FIG. 11A, a semiconductor wafer 200 is prepared on one surface of which is formed a matrix of semiconductor substrates 20 provided with the semiconductor device 22, the electrode 24, and the protective film 26. As shown in FIG. 12, the semiconductor wafer 200 is partitioned into a plurality of semiconductor module areas R by the plurality of scribe lines 120. A semiconductor module is formed in each of the semiconductor module areas R.

Then, as shown in FIG. 11B, the stress relaxation layer 60 is formed on the upper surface of the semiconductor substrate 20 by using a laminating device. The stress relaxation layer 60 is formed by an insulator such as epoxy thermosetting resin. For example, the thickness of the stress relaxation layer 60 is 30 μm.

Then, as shown in FIG. 11C, the metal layer 70 is built on the stress relaxation layer 60. The stress relaxation layer 60 also functions as an adhesive layer for adhesively attaching the metal layer 70. Like the wiring layer 40 shown in FIG. 8, the metal layer 70 is formed of copper. The metal layer 70 and the wiring layer 40 have the same coefficient of thermal expansion. The shape and thickness of the metal layer 70 are defined according to the wiring pattern of wiring layer 40. As shown in FIGS. 9A-9C, the metal layer 70 used in the first embodiment includes the flat part 72 with a flat surface and the unlevel part 74 in which the trench 74 is formed. The flat part 72 is provided in an area (hot spot) in which the temperature will be relatively high during operation. For example, the area in which the temperature is relatively high during operation is above the semiconductor device 22, which releases a large amount of heat. The trench 76 provided in the unlevel part 74 is oriented so as to connect the periphery of the semiconductor module 10 and the flat part 72. One end of the trench 76 is connected to the flat part 72. Well-known lithographic and etching steps may be used to form the trench 76 of the unlevel part 74. The insulating layer 30 is sandwiched between the bottom surface of the semiconductor substrate 20 and the copper plate 100. The thickness of the insulating layer 30 is about 60 μm, which is substantially equal to the height of the bump 41.

Then, as shown in FIG. 1D, the semiconductor substrate 20, the metal layer 70, and the insulating layer 30 are integrated by pressure molding the assembly using a press machine. The pressure and the temperature of the press work are about 5 MPa and 200° C., respectively. The press work lowers the viscosity of the insulating layer 30 so that the insulating layer 30 undergoes plastic flow. This allows the bump 41 to penetrate the insulating layer 30 so that the bump 41 and the electrode 24 of the semiconductor substrate 20 are electrically connected. Since the side part 44 of the bump 41 is formed to be progressively smaller in diameter toward the end part 43, the bump 41 penetrates the insulating layer 30 smoothly in this process.

Since the metal layer 70 is provided on a surface of the semiconductor substrate 20 opposite to the wiring layer 40, the stress developed in the semiconductor substrate 20 due to a difference in coefficient of thermal expansion between the semiconductor substrate 20 and the metal layer 70 balances the stress developed in the semiconductor substrate 20 due to a difference in coefficient of thermal expansion between the semiconductor substrate 20 and the metal layer 70, in the cooling process following the press work. This reduces the warp of the semiconductor substrate 20 so that the flatness of the semiconductor substrate 20 is improved.

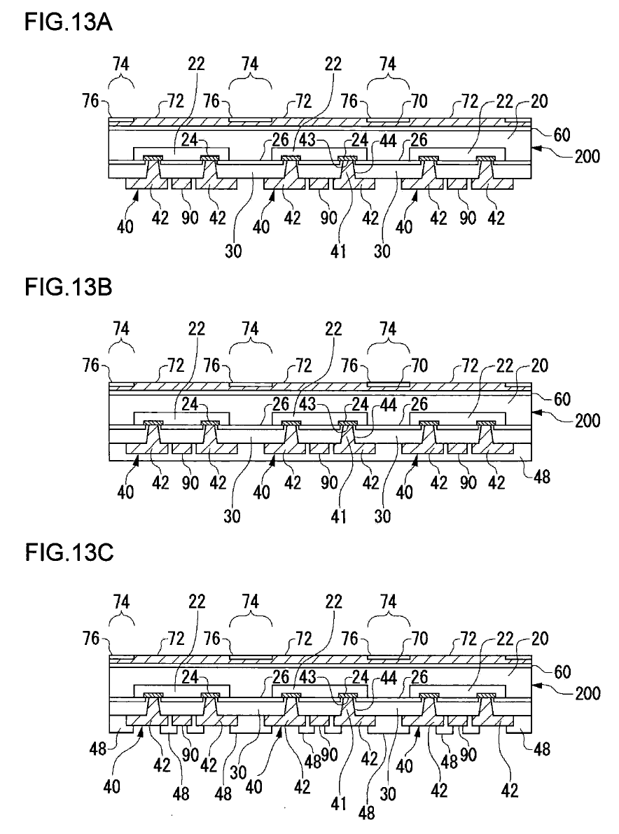

Then, as shown in FIG. 13A, by etching the entirety of the bottom surface of the copper plate 100, parts unnecessary for rewiring are removed and the thickness of the wiring layer 40 is adjusted. The thickness of the wiring layer 40 according to the first embodiment is about 30 μm.

Then, as shown in FIG. 13B, a surface roughener or the like is used to roughen the surface of the wiring layer 40. Subsequently, the photo solder resist layer 48 is built on the wiring layer 40 and the insulating layer 30 by using a laminating device.

Then, as shown in FIG. 13C, the photo solder resist layer 48 outside the area for the electrode for external connection is selectively hardened by an exposure apparatus, followed by development for removal of the electrode area. Subsequently, the photo solder resist layer 48 is further hardened by UV irradiation.

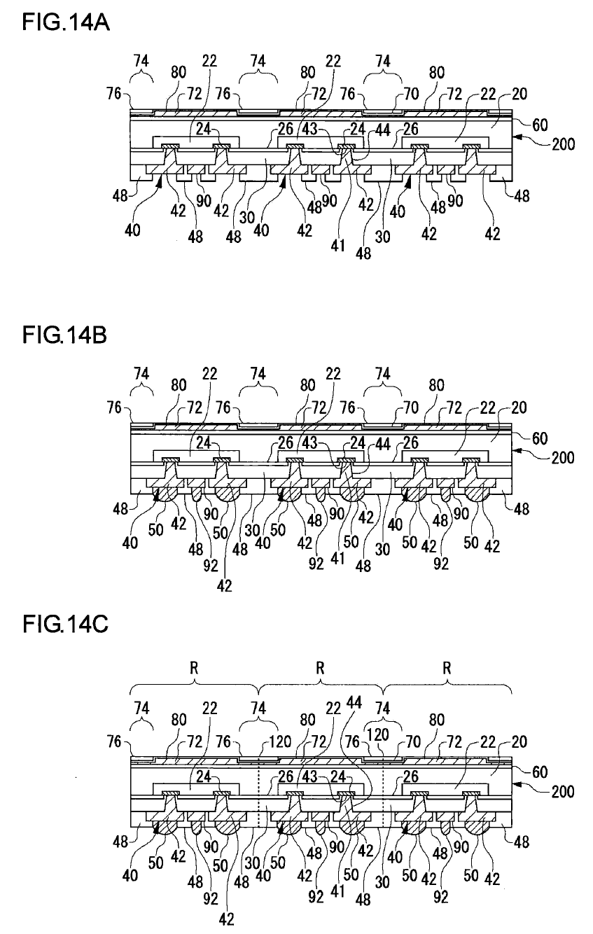

Subsequently, as shown in FIG. 14A, the high emissivity layer 80 is formed on the metal layer 70. For example, when the black paint described above is used to form the high emissivity layer 80, the metal layer 70 is coated with the black paint by a well-known painting technology. When a metal like molybdenum or titanium is used to form the high emissivity layer 80, vapor evaporation or sputtering may be employed.

Then, as shown in FIG. 14B, solder printing is used to form the electrode (solder ball) 50 which functions as a terminal for external connection in the wiring layer 40, and to form the solder ball 92 in the heat dissipating plate 90. More specifically, the electrode 50 and the solder ball 92 are formed by printing solder paste (paste mixture of resin and solder) onto a desired location using a screen mask and heating the paste to a solder melting temperature. Alternatively, the wiring layer 40 and the heat dissipation plate 90 may be coated with flux before mounting the solder ball on the wiring layer 40 and the heat dissipation plate 90.

Then, as shown in FIG. 14C, individual semiconductor modules having the same outer dimension as the semiconductor substrate 20 are produced by dicing the semiconductor wafer from beneath (underside) the wafer along the scribe lines 120 which define the plurality of semiconductor module areas R. Residue created in the process of dicing is removed by cleaning using a chemical solution.

Through these steps, the semiconductor module according to the second embodiment shown in FIG. 8 is produced.

The embodiments described are intended to be illustrative only and it will be obvious to those skilled in the art that various modifications such as design variations could be developed based upon the knowledge of a skilled person and that such modifications are also within the scope of the present invention.

In the first embodiment, the bump 1041 is formed on one surface of the copper plate 1100 and the rewiring 1042 is formed on the other surface of the copper plate 1100, as shown in FIGS. 2A-2E, before pressure-bonding the copper plate 1100 to the semiconductor substrate 1020. Alternatively, the copper plate 1100 provided with the bump 1041 on one surface, the other surface being flat, may be bonded to the semiconductor wafer before forming the rewiring 1042 by selectively removing the bottom surface of the copper plate 1100 using photolithographic steps.

In the second embodiment, the bump 41 is formed on one surface of the copper plate 100 and the rewiring 42 is formed on the other surface of the copper plate 100, as shown in FIGS. 10A-10E, before pressure-bonding the copper plate 100 to the semiconductor substrate 20. Alternatively, the copper plate 100 provided with the bump 41 on one surface, the other surface being flat, may be bonded to the semiconductor wafer before forming the rewiring 42 by selectively removing the bottom surface of the copper plate 100 using photolithographic steps.

What is claimed is:

1. A semiconductor module comprising:
a semiconductor substrate on which are formed a semiconductor device and an electrode electrically connected to the semiconductor device;
a wiring layer having a bump electrically connected to the electrode on a major surface of the semiconductor substrate;
an insulating layer provided between the semiconductor substrate and the wiring layer and adapted to undergo plastic flow when applied pressure;
an electrode for external connection electrically connected to the wiring layer;
a metal layer provided on a surface opposite to the major surface of the semiconductor substrate

2. The semiconductor module according to claim 1, wherein
the wiring layer comprises rolled metal.

3. The semiconductor module according to claim 1, wherein
a stress relaxation layer formed of an insulator is provided between the metal layer and the semiconductor substrate.

4. The semiconductor module according to claim 2, wherein
a stress relaxation layer formed of an insulator is provided between the metal layer and the semiconductor substrate.

5. A method of manufacturing a semiconductor module, comprising:
forming a wiring layer provided with a bump by working a metal plate;
pressure-bonding the wiring layer on a major surface of the semiconductor substrate via an insulating layer adapted to undergo plastic flow when applied pressure, a semiconductor device and an electrode electrically connected to the semiconductor device being formed on the semiconductor substrate; and
forming a metal layer on a surface opposite to the major surface of the semiconductor substrate.

6. The method of manufacturing a semiconductor module according to claim 5, wherein
the step of forming a metal layer and the step of pressure-bonding the wiring layer are performed simultaneously.

7. The method of manufacturing a semiconductor module according to claim 5, further comprising:
providing a stress relaxation layer formed of an insulator on a surface opposite to the major surface of the semiconductor substrate, before providing the metal layer, wherein
the metal layer is provided on a surface opposite to the major surface of the semiconductor substrate via the stress relaxation layer.

8. The method of manufacturing a semiconductor module according to claim 6, further comprising:
providing a stress relaxation layer formed of an insulator on a surface opposite to the major surface of the semiconductor substrate, before providing the metal layer, wherein
the metal layer is provided on a surface opposite to the major surface of the semiconductor substrate via the stress relaxation layer.

9. The method of manufacturing a semiconductor module according to claim 7, further comprising:
forming a semiconductor device and an electrode in each of a plurality of areas in the semiconductor substrate, and then isolating, after providing the metal layer, the individual areas each including the semiconductor device and the electrode.

10. The method of manufacturing a semiconductor module according to claim 8, further comprising:
forming a semiconductor device and an electrode in each of a plurality of areas in the semiconductor substrate, and then isolating, after providing the metal layer, the individual areas each including the semiconductor device and the electrode.

11. A semiconductor module comprising:
a semiconductor substrate on which are formed a semiconductor device and an electrode electrically connected to the semiconductor device;
a wiring layer electrically connected to the electrode on a major surface of the semiconductor substrate;
an insulating layer provided between the semiconductor substrate and the wiring layer;
an electrode for external connection electrically connected to the wiring layer;
a metal layer provided on a surface opposite to the major surface of the semiconductor substrate; and
a high emissivity layer provided on the metal layer.

12. The semiconductor module according to claim 11, wherein
the surface of an area in the metal layer characterized by relatively high temperature during operation is flat, and a trench is formed on the surface of the area characterized by relatively low temperature during operation.

13. The semiconductor module according to claim 12, wherein
an end of the trench is connected to the flat part.

14. A method of manufacturing a semiconductor module, comprising:
forming, via an insulating layer, a wiring layer on a major surface of a semiconductor substrate on which are formed a semiconductor device and an electrode electrically connected to a semiconductor device;
forming a metal layer on a surface opposite to a major surface of the semiconductor substrate; and
forming a high emissivity layer on the metal layer.

15. The method of manufacturing a semiconductor module according to claim 14, wherein
the step of forming the metal layer and the step of pressure-bonding the wiring layer are performed simultaneously.

16. The method of manufacturing a semiconductor module according to claim 14, further comprising:
forming a trench in an area of the surface of metal layer characterized by relatively low temperature during operation, before forming the high emissivity layer.

17. The method of manufacturing a semiconductor module according to claim 16, wherein
an end of the trench is connected to an area of the surface of the metal layer characterized by relatively low temperature during operation.
